(19) United States
(12) Patent Application Publication
(10) Pub. No.: US 2010/0163952 A1
(43) Pub. Date: Jul. 1, 2010

(54) Flash Cell with Integrated High-K Dielectric and Metal-Based Control Gate

(76) Inventors: Chia-Hong Jan, Portland, OR (US); Walid M. Hafez, Portland, OR (US)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/347,904

(22) Filed: Dec. 31, 2008

(51) Int. Cl. H01L 29/66; H01L 21/336; H01L 21/04; H01L 29/41

(52) U.S. Cl. 257/315; 438/257; 257/E21.04; 257/E29.112

(57) ABSTRACT

A semiconductor device is described having an integrated high-k dielectric layer and metal control gate. A method of fabricating the same is described. Embodiments of the semiconductor device include a high-k dielectric layer disposed on a floating gate. The high-k dielectric layer defines a recess. A metal control gate is formed in the recess.

### FIELD

Embodiments of the invention relate to integrated circuit fabrication and, in particular, to a flash cell having an integrated high-k dielectric and metal-based control gate.

### BACKGROUND

Standard dual-gate flash cells typically include a control gate and a floating gate made of polycrystalline silicon (polysilicon). The floating gate is typically formed on a gate oxide layer typically made of silicon dioxide. The control gate and floating gate are typically separated by inter-polysilicon dielectric (IPD) layer typically made of silicon dioxide. When a voltage is applied to the control gate, charges from the silicon substrate are deposited into the floating gate through the gate oxide layer via Fowler-Nordheim tunneling or hot carrier injection mechanisms.

The fabrication of standard dual-gate flash cells typically requires two separate depositions of polysilicon to form the control gate and floating gate. As the current technology continues to drive towards smaller device size, the fabrication process window typically becomes narrower and the process flow becomes more complicated and difficult to control. For example, the process steps between the patterning and deposition of polysilicon to form the control gate and floating gate present very narrow process margins.

### BRIEF DESCRIPTION OF THE DRAWINGS

Embodiments of the present invention are illustrated by way of example and not limited in the figures of the accompanying drawings, in which like references indicate similar elements.

FIG. 1 is a cross-sectional view of an embodiment of a flash cell having a high-k dielectric layer formed between a metal control gate and a floating gate.

FIGS. 2-4 are cross-sectional views of a flash cell at different stages of formation of a floating gate, a high-k dielectric layer, and a metal control gate.

### DETAILED DESCRIPTION

Embodiments of the invention relate to flash cells fabricated from materials different from those typically used to form the control gate, the floating gate, and the dielectric layer between the control gate and floating gate. The use of silicon dioxide and polysilicon is minimized as only single polysilicon deposition step is required to form the floating gate. High-k dielectric material is used to form the dielectric layer between the control gate and the floating gate. A metal-based material is used to form the control gate. The formation of gate electrodes is further enhanced by the inherent self-alignment feature exhibited by the deposition characteristics of the materials for the gate electrodes. The method of fabrication of embodiments of the flash cell is compatible with the current fabrication technology and requires minimal modifications.

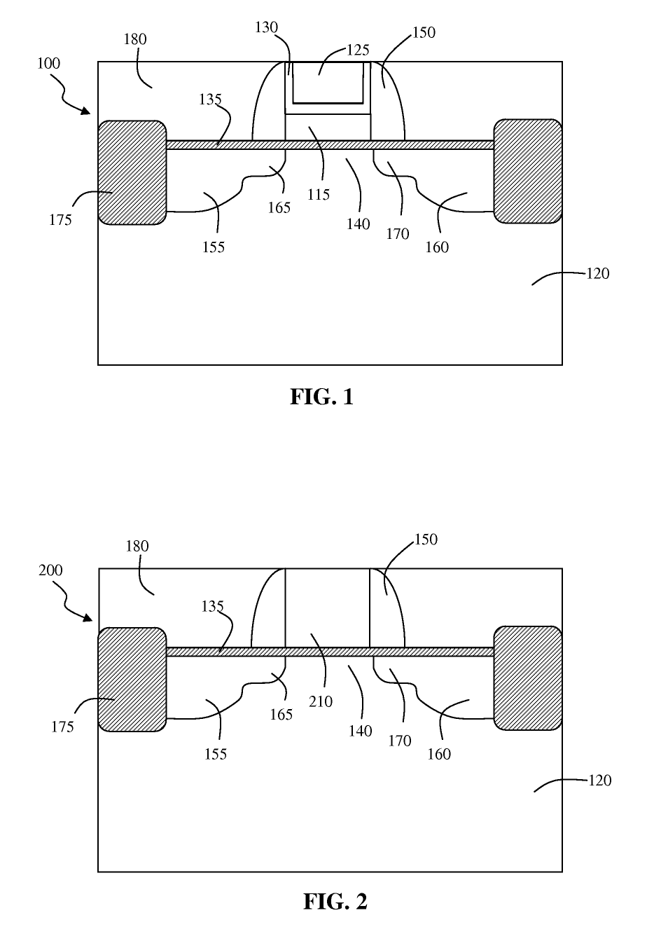

FIG. 1 is a cross-sectional view of an embodiment of a flash cell having a high-k dielectric layer formed between a metal control gate and a floating gate. Flash cell 100 includes gate oxide layer 135 formed on an upper surface of semiconductor substrate 120. Floating gate 115 is formed on gate oxide layer 135. Gate oxide layer 135 insulates floating gate 115 from channel region 140. High-k dielectric layer 130 is formed on floating gate 115. Metal-based control gate 125 is formed on high-k dielectric layer 130. Control gate 125 is insulated from floating gate 115 by high-k dielectric layer 130. Metal-based control gate 125, high-k dielectric layer 130, and floating gate 115 are interposed between sidewall spacers 150. Source region 155 and drain region 160 are formed in semiconductor substrate 120. Substrate 120 also includes shallow source extension region 165 and shallow drain extension region 170. Isolation regions 175 isolate flash cell 100 from adjacent flash cells 100 (not shown). For an embodiment, inter-layer dielectric (ILD) layer 180 is formed on gate oxide layer 135 and is planar with metal-based control gate 125.

Semiconductor substrate 120 includes any semiconductor material to make a variety of integrated circuits including passive and active devices. Semiconductor substrate 120 also includes monocrystalline silicon and silicon-on-insulator (SOI) structure. For an embodiment, substrate 120 is germanium, gallium arsenide, gallium antimonide or other materials suitable as foundation upon which flash cells 100 are fabricated. Flash cell 100 is connected to one or more metallization layers of integrated circuits having active and/or passive devices, such as transistors, switches, optoelectronic devices, capacitors, and interconnects. The one or more metallization layers of integrated circuits are separated from adjacent metallization layers by dielectric material such as ILD layer.

Gate oxide layer 135 is made of any dielectric material capable of insulating floating gate 115 from source region 155 and drain region 160. For an embodiment, gate oxide layer 135 is silicon dioxide. For another embodiment, gate oxide layer 135 is silicon nitride. For an embodiment, gate oxide layer 135 includes silicon oxynitride. The thickness of gate oxide layer 135 depends on the scaling requirements of the device technology so that the entire gate structure of flash cell 100 permits induction of charges from semiconductor substrate 120 through gate oxide layer 135. The thickness of gate oxide layer 135 also depends on the size of voltage applied to metal-based control gate 125. For an embodiment, the thickness of gate oxide layer 135 is 20-60 Å. Gate oxide layer 135 can be either deposited or grown. For an embodiment, gate oxide layer 135 is thermally grown by chemically reacting silicon and oxygen at elevated temperature range between 750-1100° C.

Floating gate 115 stores data in flash cell 100. Floating gate 115 may be made of polysilicon. For an embodiment, the thickness of floating gate 115 is 300-400 Å. Floating gate 115 may be formed using a conventional deposition and patterning method. Polysilicon floating gate may be formed using low pressure chemical vapor deposition (LPCVD) where silane disassociates to silicon and hydrogen, and polysilicon is then deposited on gate oxide layer 135. The deposition temperature is moderately low in the range of 570-650° C. Polysilicon is masked and patterned to form fine polysilicon gate structures on gate oxide layer 135.

High-k dielectric layer 130 insulates metal-based control gate 125 from floating gate 115. For an embodiment, high-k dielectric layer 130 is disposed directly between metal-based control gate 125 and floating gate 115. For an embodiment, high-k dielectric layer 130 is a conformal layer formed on floating gate 115, and the side walls of high-k dielectric layer 130 are adjacent to a portion of the inner surface of sidewall spacers 150. High-k dielectric layer 130 defines a recess filled by metal-based control gate 125. For an embodiment, high-k dielectric layer 130 has a uniform thickness of 40-60 Å. High-k dielectric layer 130 includes an oxide of a metal that has dielectric constant (k) higher than the dielectric constant of silicon dioxide. For an embodiment, high-k dielectric layer 130 is hafnium oxide. Other embodiments may include high-k dielectric layer 130 made from any materials capable of minimizing gate leakage such as, but not limited to, hafnium silicon oxide, lanthanum oxide, zirconium oxide, zirconium silicon oxide, titanium oxide, tantalum oxide, barium strontium titanium oxide, barium titanium oxide, strontium titanium oxide, yttrium oxide, aluminum oxide, lead scandium oxide, and lead zinc niobate.

For an embodiment, metal-based control gate 125 is formed in a recess defined by high-k dielectric layer 130. For an embodiment, the top surface of metal-based control gate 125 is planar with ILD layer 180. Metal-based control gate 125 is a conductive metal-based layer having high tolerance to relatively high temperatures such as temperatures exceeding 900° C. Embodiments may include metal-based control gate 125 made of one of the group of metals comprising tungsten, copper, ruthenium, cobalt, chromium, iron, palladium, molybdenum, tantalum, manganese, vanadium, gold, silver, and niobium. Metal-based control gate 125 may also be made from metal alloys comprising any of said metals. For another embodiment, metal-based control gate 125 is made from a less conductive metal carbide such as titanium carbide, zirconium carbide, tantalum carbide, tungsten carbide, and tungsten carbide. Other embodiments include metal-based control gate 125 made from a metal nitride such as titanium nitride and tantalum nitride, or a conductive metal oxide such as ruthenium oxide. For an embodiment, the thickness of metal-based control gate 125 is 300-400 Å.

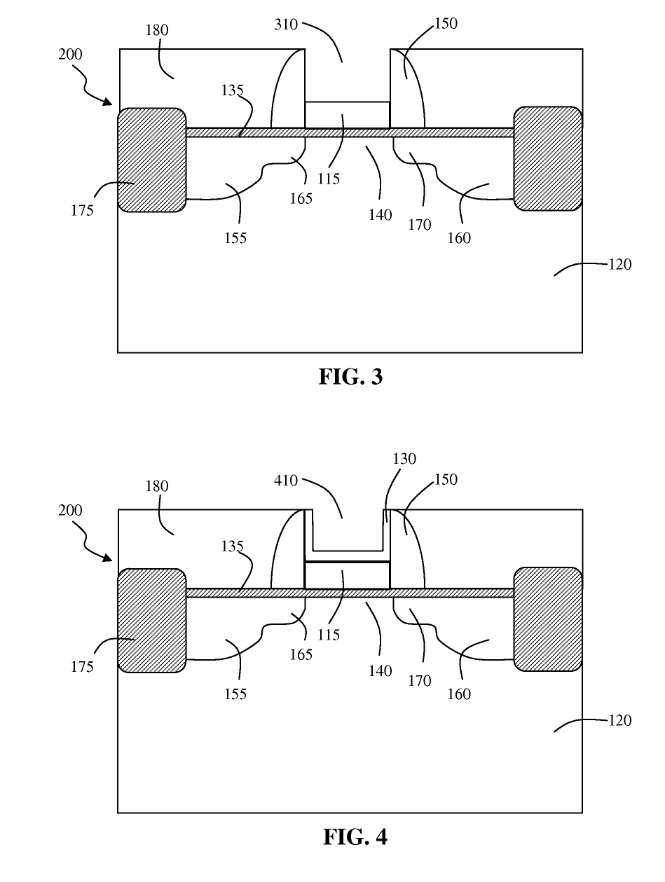

FIGS. 2-4 are cross-sectional views of a flash cell at different stages of formation of a floating gate, a high-k dielectric layer and a metal control gate according to an embodiment. Referring to FIG. 2, a semiconductor body 200 is fabricated up to the formation of ILD layer 180, sidewall spacers 150, polysilicon layer 210, gate oxide layer 135. Polysilicon layer 210 is formed on gate oxide layer 135 and is interposed between sidewall spacers 150. Gate oxide layer 135 may be first formed on semiconductive substrate 120, sequentially followed by polysilicon layer 210, sidewall spacers 150 and ILD layer 180. Gate oxide layer 135, polysilicon layer 210, sidewall spacers 150, and ILD layer 180 may be formed by way of any conventional methods known to a person of ordinary skill in the art. For an embodiment, polysilicon layer 210 is planar with ILD layer 180. For an embodiment, the initial thickness of polysilicon layer 210 is 800-1000 Å. For an embodiment, the initial width of polysilicon layer 210 is 1000-10000 Å. For an embodiment, the initial length of polysilicon layer 210 is 400-10000 Å.

Next, polysilicon layer 210 is partially removed to form floating gate 115 using methods known to a person skilled in the art. FIG. 3 is a cross-sectional view of an embodiment of a flash cell having a portion of polysilicon layer 210 being partially removed to form recess 310 defined between the inner surface of sidewall spacers 150 and the top surface of floating gate 115. A portion of the thickness of polysilicon layer 210 is removed while the width and length of polysilicon layer 210 remain. For an embodiment, the thickness of floating gate 125 after partial removal of polysilicon layer 210 is 300-400 Å. For another embodiment, the thickness of floating gate 125 after partial removal of polysilicon layer 210 is approximately 50% of the initial thickness. For an embodiment, floating gate 125 is formed by way of selectively etching polysilicon layer 210. For an embodiment, plasma etching (dry etching) is employed. For an embodiment, a masking layer is used to pattern and define polysilicon layer 210 so that only polysilicon layer 210 is removed by plasma etching. For an embodiment, polysilicon layer 210 is anisotropically etched to form floating gate 115 having substantially planar top surface. Fluorine-based plasma etch gas chemistries including CF₄, CF₄/O₂, SF₆, C₂F₆/O₂ and NF₃ is used. Plasma etch gas containing chlorine or bromine may be used. Wet-etching may also be employed to remove a portion of polysilicon layer 210 to form floating gate 115. During wet-etching, semiconductive body 200 is immersed or sprayed with etching acid solution. An etching solution having high etching selectivity for silicon and low selectivity for oxide or silicode is used. For example, polysilicon layer 210 is etched using a solution of hydrofluoric acid and nitric acid buffered with acetic acid or deionized water. Potassium hydroxide (KOH) may also be used as etching chemical. A combination of plasma etching and wet etching can be employed.

After floating gate 125 has been partially removed, high-k dielectric layer 130 is formed. High-k dielectric layer 130 is deposited on floating gate 125. FIG. 4 is a cross-sectional view of an embodiment of flash cell having high-k dielectric layer 130 formed on floating gate 115. For an embodiment, high-k dielectric layer 130 is formed on the top surface of floating gate 115 and on a portion of the inner surface of sidewall spacers 150. For an embodiment, high-k dielectric layer 130 is a conformal layer deposited on floating gate 115 and on a portion of sidewall spacers 150. By being a conformal layer, the thickness of high-k dielectric layer 130 on the top surface of floating gate 115 is uniform with the thickness of high-k dielectric layer 130 on a portion of the inner surface of sidewall spacers 150. For an embodiment, the thickness of high-k dielectric layer 130 is 40-60 Å. High-k dielectric layer 130 defines recess 410. For an embodiment, recess 410 has a height between 300-400 Å. High-k dielectric layer 130 may be deposited by way of any method known to a person skilled in the art. For example, high-k dielectric layer 130 may be deposited by way of chemical vapor deposition (CVD) method. During CVD, gas molecules of reactant gases combine to form isolated island clusters and subsequently coalesce to form a continuous film of high-k dielectric layer 130 spreading across the top surface of floating gate 115. Examples of implementation of CVD method which may be used are atmospheric pressure CVD (APCVD), low pressure CVD (LPCVD) and plasma enhanced CVD (PECVD). Alternatively, atomic layer disposition (ALD) may be used to form high-k dielectric layer 130. In ALD, a layer-by-layer adsorption of and reaction between molecules of reactant gases on the top surface of floating gate 115 takes place to form conformal high-k dielectric layer 130.

Next, metal-based control gate 125 is formed. For an embodiment, metal-based control gate 125 is formed in recess 410. For an embodiment, metal-based control gate 125 is formed by filling recess 410 with metal-based material. For an embodiment, metal-based control gate 125 is planar with ILD layer 180. Various metal deposition methods are known to a person skilled in the art to form metal-based control gate 125. For example, metal-based control gate 125 may be formed by way of a chemical process such as chemical vapor deposition (CVD). Alternatively, electroplating method is used to first form a metal seed layer on the surface of recess 410 and subsequently grow metal-based control gate 125 to completely fill recess 410. In another example, electroless plating method is used. Other physical processes may also be used to form metal-based control gate 125. For example, physical vapor deposition (PVD) (also known as sputtering) is used to form metal-based control gate 125. After forming metal-based control gate 125, an embodiment of flash cell 100 as illustrated in FIG. 1 is formed.

In the foregoing specification, reference has been made to specific embodiments of the invention. It will, however be evident that various modifications and changes may be made thereto without departing from the broader spirit and scope of the invention. The specification and drawings are, accordingly, to be regarded in an illustrative rather than restrictive sense.

What is claimed is:

1. A semiconductor device, comprising:
a first dielectric layer disposed on a semiconductive body;
a floating gate disposed on the first dielectric layer;
a high dielectric constant (high-k) dielectric layer disposed on the floating gate, the high-k dielectric layer defining a recess; and
a metal gate disposed in the recess.

2. The device of claim 1, wherein the floating gate, the high-k dielectric layer and the metal gate are interposed between a plurality of sidewall spacers formed on the first dielectric layer.

3. The device of claim 2, wherein the floating gate, the high-k dielectric layer, the metal gate and the sidewall spacers are disposed in an inter layer dielectric (ILD) layer.

4. The device of claim 3, wherein the ILD layer is planar with the metal gate.

5. The device of claim 4, wherein the high-k dielectric layer is a conformal layer of thickness between 1-10 Å.

6. The device of claim 5, wherein the metal gate is 300-400 Å thick.

7. The device of claim 6, wherein the first dielectric layer is 20-50 Å thick.

8. The device of claim 7, further comprising a source region, a drain region, a channel region formed in the semiconductive body and below the first dielectric layer.

9. A method to form a semiconductor device, comprising:
forming a first dielectric layer on a semiconductive body;
forming a floating gate on the first dielectric layer;
forming a high dielectric constant (high-k) dielectric layer on the floating gate, the high-k dielectric layer defining a recess; and
forming a metal gate in the recess.

10. The method of claim 9, further comprising partially removing a portion of the thickness of the first dielectric layer.

11. The method of claim 10, wherein the floating gate, the high-k dielectric layer and the metal gate are interposed between a plurality of sidewall spacers formed on the first dielectric layer.

12. The method of claim 11, wherein the floating gate, the high-k dielectric layer, the metal gate and the sidewall spacers are disposed in an inter layer dielectric (ILD) layer.

13. The method of claim 12, wherein the ILD layer is planar with the metal gate.

14. The method of claim 13, wherein the high-k dielectric layer is a conformal layer of thickness between 1-10 Å.

15. The method of claim 14, wherein forming the recess in the high-k dielectric layer includes depositing the high-k dielectric layer on the floating gate by way of atomic layer deposition.

16. The method of claim 15, wherein the metal gate is 300-400 Å thick.

17. The method of claim 16, wherein the first dielectric layer is 20-50 Å thick.
